(19) United States
(12) Patent Application Publication
(10) Pub. No.: US 2005/0164522 A1
(43) Pub. Date: Jul. 28, 2005

(54) Optical fluids, and systems and methods of making and using the same

(76) Inventors: Roderick R. Kunz, Acton, MA (US); Michael Switkes, Somervile, MA (US); Roger S. Sinta, Woburn, MA (US)

Correspondence Address: FOLEY HOAG, LLP;PATENT GROUP, WORLD TRADE CENTER WEST, 155 SEAPORT BLVD, BOSTON, MA, 02110, US

(21) Appl. No.: 10/395,703

(22) Filed: Mar. 24, 2003

(51) Int. Cl. H01L 21/469; G02B 1/12

(52) U.S. Cl. 438/780; 438/795; 252/582

(57) ABSTRACT

In part, the present invention is directed towards a fluid composition, and systems and methods of making and using the same, wherein the fluid composition has an absorbance of less than about 2 cm⁻¹.

### GOVERNMENT SUPPORT

The subject invention was made in part with support from the U.S. Government under a grant from the Defense Advanced Research Project Agency. Accordingly, the U.S. Government has certain rights in this invention.

### BACKGROUND OF THE INVENTION

Optical systems, such as collection and projection optical systems, are often used to form or resolve high-resolution patterns, for example, images, scanning spots, and interference patterns. One exemplary example of such optical systems are photolithographic systems. In certain photolithographic systems, for example, light is projected onto a resist for the purpose of patterning an electronic device. Photolithographic systems have been a mainstay of semiconductor device patterning for at least the last three decades.

In a typical photolithographic system, the resolution r₀ of a photolithographic system having a given lithographic constant k₁, is given by the equation:
r₀=k₁λ/NA (1)
where λ is the operational wavelength, and numerical aperture (NA) is given by the equation
NA=n sin θ₀ (2)

Angle θ₀ is the angular semi-aperture of the system, and n is the refractive index of the material filling the space between an optical system and a focal surface, for example, a focal surface to be patterned.

Continuing efforts have been made to improve resolution in optical systems, such as photolithographic systems. Generally, there are at least three conventional methods of resolution improvement for optical resolution and photolithographic technology. Some progress has been achieved in reducing the wavelength λ from the mercury g-line (436 nm) to a 193 nm excimer laser, and even down to 157 nm. Resolution improvement using extreme-ultraviolet (EUV) wavelengths is also being pursued.

Implementation of resolution enhancement techniques (RETs) such as phase-shifting masks, and off-axis illumination have lead to a reduction in the lithographic constant k₁ from about 0.6 to values approaching 0.4. Numerical aperture (NA) parameters have been improved with enhanced optical designs, manufacturing techniques, and metrology. Such improvements have lead to increases in NA from approximately 0.35 to greater than 0.7. For free-space optical systems where n−1, equation (2) can be seen to bound NA to values of one or less.

Submicrometer-scale optical imaging, as used, for example, in metrologic or lithographic applications, may require close proximity between a focal plane or surface and the final element of the imaging optics. When the space between a focal plane or surface and the final element of the imaging optics is filled with a fluid having a refractive index higher than 1.0, smaller features may be resolved and an imaging system including such a fluid exhibits improved resolution.

Immersion lithography, for example, provides one possibility for increasing the numerical aperture NA of an optical system, such as a lithographic system. In immersion lithography, a substrate may be immersed in a fluid or immersion medium that has, for example, a high index, such that a space between a final optical element and a focal surface, for example, a substrate, is filled with the fluid. Accordingly, immersion techniques may provide a possibility of increasing numerical aperture beyond the free-space theoretical limit of one.

The desire to develop immersion systems is growing more acute because the ability to achieve resolution improvements via conventional means, such as wavelength reduction, appears to be increasingly difficult, particularly at wavelengths below 220 nm. In addition, with numerical apertures produced by free-space lithographic methods approaching the theoretical limit, progress using conventional methods would appear to be bounded.

In part, the present invention is directed toward fluids that are compatible with lithographic systems, particularly those systems having an operative wavelength below 220 nm.

### SUMMARY OF THE INVENTION

In part, the present invention is directed to compositions that are in the liquid state when used in optical and other systems and that have desirable optical characteristics at various wavelengths, and methods and systems of making and using the same.

In one aspect, the present invention is directed to compositions that are purified sufficiently so that the absorbance at a particular wavelength(s), such as 157 nm, is below a certain level, such as 5.0 cm⁻¹. In exemplary compositions, such as those containing one or more perfluoroethers, the purity of the perfluoroethers and the other components is such that the desired optical characteristic(s) is obtained. It may be the case that already known compounds, such as perfluoroethers, may be used in the subject compositions once purified sufficiently (or alternatively, synthesized or otherwise prepared in a sufficiently purified form). In part and for certain embodiments, the present invention teaches the level of purity required for, and means of achieving such purity level, observed to be necessary to attain desired optical characteristic(s).

In one embodiment, for example, a subject composition comprises at least one perfluoroether compound, such that the absorbance of such composition is less than about 10, 7.5, 5, 3, 2, 1. 0.9, 0.75 or less than about 0.5 cm⁻¹ at a wavelength of about 157 nm (or another designated wavelength or wavelengths, usually below 220 nm). In certain other embodiments, the subject composition is a fluid or liquid composition with a purity of at least about 99.99%, or at least about 99.999% by weight.

In certain embodiments, the subject compositions have the structures described in greater detail below, all of which structures are hereby incorporated by reference in their entirety into this Summary to describe the present invention. In addition, the claims appended hereto are hereby incorporated into this Summary in their entirety.

The present invention provides for methods of making the subject compositions, and the various components thereof.

In one aspect, the present invention comprises a system for optical imaging or a system for optical etching comprising an illumination source capable of producing light with, for example, a wavelength of about 157 nm, and a focal surface or focal plane, an imaging optic, and a subject composition.

In another aspect, the present invention is directed toward a process of modifying a substrate or wafer (such as a silicon wafer), including providing a substrate, which may further comprise a photoresist, mask layer or other layer or surface that may be optically sensitive, providing an imaging optic, introducing a subject composition, and illuminating light through the fluid composition onto the substrate, thereby creating a printed pattern, or etch, or other feature on the substrate.

In a further aspect, a semiconductor device is provided, which comprises a printed pattern, an etch or etching, or other features. The features have, in one embodiment, a width less than about 30 nm. The semiconductor device is made by a process comprising introducing a subject composition into a volume between a silicon wafer comprising a photoresist layer, and an imaging optic, and directing optical energy through subject composition onto the silicon wafer.

The subject compositions may have uses in addition to those based on their optical properties. For example, as described in more detail below, compositions that have a certain purity level may be useful in those applications in which purity may be important or valuable. Other uses of the subject compositions will be known to those of skill in the art.

In other embodiments, the present invention contemplates a kit including subject compositions, and optionally instructions for their use. Uses for such kits include, for example, immersion lithography.

These embodiments of the present invention, other embodiments, and their features and characteristics, will be apparent from the description, drawings and claims that follow.

### BRIEF DESCRIPTION OF THE DRAWINGS

These and other features and advantages of the fluids, systems and processes disclosed herein will be more fully understood by reference to the following illustrative, non-limiting detailed description in conjunction with the attached drawings in which like reference numerals refer to like elements throughout the different views. The drawings illustrate principals of fluids, systems and processes disclosed herein and, although not to scale, show relative dimensions.

FIG. 1 shows a schematic illustration of an immersion lithography system.

FIG. 2 illustrates the absorbance of an exemplary fluid as a function of fraction of unsaturated compounds.

FIG. 3 shows the absorbance as a function of wavelength for a degassed perfluoro-15-crown-5 fluid.

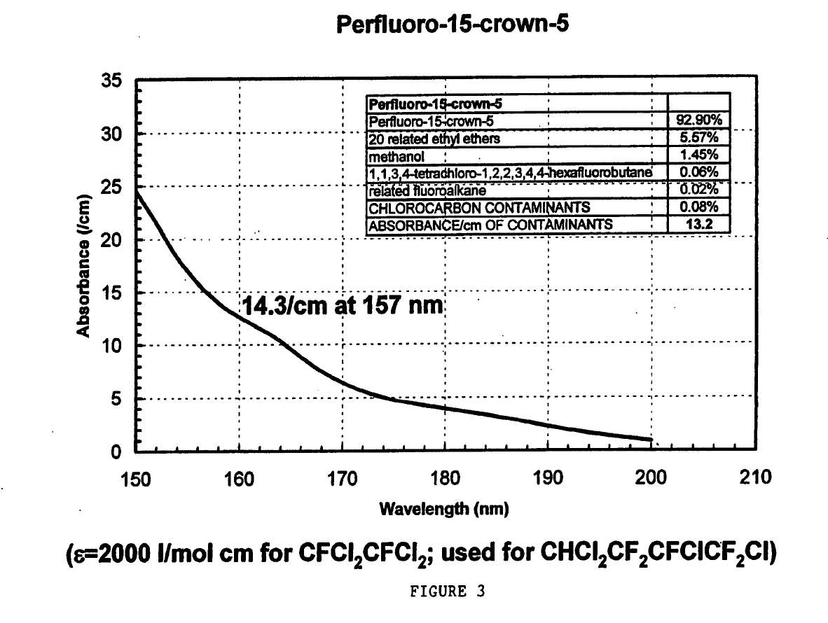

FIG. 4 provides a table showing the purity by weight of several commercially available perfluoroethers (identified as A, B, C and D in the columns of the table).

FIG. 5 illustrates the spectrum of a sample of a specially ordered perfluorotriglyme as described in the Materials section of the Exemplification, which has an absorbance of about 1.1 cm⁻¹ at a wavelength of about 157 nm. The absorbance of this sample of perfluorotriglyme is about 0.2 cm⁻¹ at a wavelength of about 200 nm.

FIGS. 6(A) and (B) illustrates gas chromatographs of (A) a sample of the material used to produce FIG. 5, and (B) the second fraction collected upon distillation of a sample of such material, as described in Example 2. As a comparison of the two gas chromatograph shows, various impurities are reduced upon distillation.

FIG. 7 illustrates the VUV spectra of (A) a sample of the material used to produce FIG. 5 and the gas chromatograph shown in FIG. 6(A) (“as received”), and (B) the second fraction collected upon distillation of a sample of such material (“cut 2”), as described in Example 2 and for which a gas chromatograph is shown in FIG. 6(B). The more highly purified material, cut 2, shows reduced absorbance below 220 nm.

FIGS. 8(A) and (B) illustrates gas chromatographs of (A) the sample used in FIG. 5, and (B) a sample of such material purified by column purification as described in Example 4. As a comparison of the two gas chromatograph shows, various impurities are reduced after column purification.

### DETAILED DESCRIPTION OF THE INVENTION

The present invention is directed in part towards fluid compositions comprising fluorinated compounds, where the fluid composition has low absorbance at light wavelengths of less than or equal to about 220 nm. In some embodiments, the fluid composition has absorbance of less than about 5 cm⁻¹. It has been learned that the optical properties described and taught for the subject compositions may be achieved by, for example, having compositions of at least a certain purity level.

Definitions

For convenience, before further description of the present invention, certain terms employed in the specification, examples and appended claims are collected here. These definitions should be read in light of the remainder of the disclosure and understood as by a person of skill in the art. Unless defined otherwise, all technical and scientific terms used herein have the same meaning as commonly understood by a person of ordinary skill in the art.

The articles “a” and “an” are used herein to refer to one or to more than one (i.e., to at least one) of the grammatical object of the article. By way of example, “an element” means one element or more than one element.

The terms “comprise” and “comprising” are used in the inclusive, open sense, meaning that additional elements may be included.

The term “including” is used to mean “including but not limited to”. “Including” and “including but not limited to” are used interchangeably.

The term “absorption” refers to the ratio of the light intensity absorbed by a sample to the intensity incident on it.

The term “transmission” refers to the ratio of light intensity transmitted by a sample to the intensity incident on it.

The term “absorbance” refers to the property of a material represented by α in the following equation:
T=10^{αx} (3)
where T is the transmission of the material and x is the path length of the light through the sample.

The term “purified” refers to an object specie(s) that is the predominant species present (i.e., on a molar or weight basis it is more abundant than any other individual species in the composition). Generally, a purified composition will have object specie(s) or an object composition that comprises about, or is greater than about 99%, 99.9%, about 99.99%, about 99.999% or even about 99.9999% by weight of the purified composition. An object composition may have one or more species in the purified fraction. For example, in the present disclosure, a fluid composition may comprise one or more species of perfluoroether compounds and still be treated as purified.

The object specie(s) or object composition may be purified to essential homogeneity (contaminant species cannot be detected in the purified composition by conventional detection methods) wherein the purified composition consists essentially of the desired specie(s) or a single object composition. Purity of a purified composition may be determined by a number of methods known to those of skill in the art, including for example gas or liquid chromatography, mass spectrometry, NMR, IR spectroscopy or Raman spectroscopy, and melting or boiling point. For example, having a purity which is least, for example, about 99.99% by weight or molar mass should be understood as meaning that the composition has less than or equal to about 0.01% impurities by weight or molar mass.

The prefix “perfluoro” refers to a compound where at least about 50%, 75% or 90% of the hydrogen atoms directly bonded to a carbon atom have been replaced with fluorine atoms. In some embodiments, a perfluoro compound is a compound having substantially all or all such hydrogen atoms replaced with fluorine atoms.

A “perfluoroether” or “perfluoroether compound” refers to a perfluoro compound comprising at least one ether moiety. Perfluoroether compounds generally have at least 4 carbon atoms, and may include perfluoropolyethers. A perfluoroether compound may be branched, linear or cyclic. Exemplary perfluoroethers include perfluoro(ethylene glycol, dimethyl ether), perfluoro(ethylene glycol, diethyl ether), perfluoro(ethylene glycol) oligomers, perfluoro(propyl ether), and perfluoro-15-crown-5 cyclic ether. In certain instances, a perfluoroether compound does not contain any unsaturated bonds, such as an alkene, alkyne, carbonyl, aromatic or heteroaromatic.

A “focal surface” is a surface that is perpendicular to the principal axis and the plane of the surface passes through the focal point of the axis of an imaging optic.

An “imaging optic” is any device through which light may pass through. Exemplary imaging optics include lens, mirrors, and projection optical devices.

“Photolithography” refers to a semiconductor fabrication process that is widely used for patterning material layers on a semiconductor wafer, structure or substrate. The material layers may be non-metal (e.g. silicon, polysilicon), metal (e.g. aluminum), etc. In the typical process, a layer of photoresist is formed over the material layer to be patterned, and exposed to light whose spatial intensity distribution usually corresponds to the desired pattern. Light of sufficient intensity incident on the photoresist is designed to cause a chemical or other reaction in the underlying areas of the photoresist. In may instances, the reaction may be such that the exposed areas are dissolved away when the wafer is exposed to a developing solution or conversely that all but the exposed areas are dissolved away upon development.

A patterned “photoresist layer” on the surface of a substrate has openings which correspond to the pattern created by the exposing illumination. In certain instances, the patterned photoresist layer may then used as an etch mask such that areas of the material layer which are exposed by the openings in the photoresist layer will be selectively removed upon exposure to an appropriate etching solution.

The term “aliphatic” is art-recognized and refers to a linear, branched, cyclic alkane, alkene, or alkyne. In certain embodiments, aliphatic groups in the present disclosure are linear or branched and have from 1 to about 20 carbon atoms.

The term “alkyl” is art-recognized, and includes saturated aliphatic groups, including straight-chain alkyl groups, branched-chain alkyl groups, cycloalkyl (alicyclic) groups, alkyl substituted cycloalkyl groups, and cycloalkyl substituted alkyl groups. In certain embodiments, a straight chain or branched chain alkyl has about 30 or fewer carbon atoms in its backbone (e.g., C₁-C₃₀ for straight chain, C₃-C₃₀ for branched chain), and alternatively, about 20 or fewer. Likewise, cycloalkyls have from about 3 to about 10 carbon atoms in their ring structure, and alternatively about 5, 6 or 7 carbons in the ring structure. The term “alkyl” is also defined to include halosubstituted alkyls.

Moreover, the term “alkyl” (or “lower alkyl”) includes “substituted alkyls”, which refers to alkyl moieties having substituents replacing a hydrogen on one or more carbons of the hydrocarbon backbone. Such substituents may include, for example, a hydroxyl, a carbonyl (such as a carboxyl, an alkoxycarbonyl, a formyl, or an acyl), a thiocarbonyl (such as a thioester, a thioacetate, or a thioformate), an alkoxyl, a phosphoryl, a phosphonate, a phosphinate, an amino, an amido, an amidine, an imine, a cyano, a nitro, an azido, a sulfhydryl, an alkylthio, a sulfate, a sulfonate, a sulfamoyl, a sulfonamido, a sulfonyl, a heterocyclyl, an aralkyl, or an aromatic or heteroaromatic moiety. It will be understood by those skilled in the art that the moieties substituted on the hydrocarbon chain may themselves be substituted, if appropriate. For instance, the substituents of a substituted alkyl may include substituted and unsubstituted forms of amino, azido, imino, amido, phosphoryl (including phosphonate and phosphinate), sulfonyl (including sulfate, sulfonamido, sulfamoyl and sulfonate), and silyl groups, as well as ethers, alkylthios, carbonyls (including ketones, aldehydes, carboxylates, and esters), —CN and the like. Exemplary substituted alkyls are described below. Cycloalkyls may be further substituted with alkyls, alkenyls, alkoxys, alkylthios, aminoalkyls, carbonyl-substituted alkyls, —CN, and the like.

The term “aralkyl” is art-recognized and refers to an alkyl group substituted with an aryl group (e.g., an aromatic or heteroaromatic group).

The terms “alkenyl” and “alkynyl” are art-recognized and refer to unsaturated aliphatic groups analogous in length and possible substitution to the alkyls described above, but that contain at least one double or triple bond respectively.

Unless the number of carbons is otherwise specified, “lower alkyl” refers to an alkyl group, as defined above, but having from one to about ten carbons, alternatively from one to about six carbon atoms in its backbone structure. Likewise, “lower alkenyl” and “lower alkynyl” have similar chain lengths.

The term “heteroatom” is art-recognized and refers to an atom of any element other than carbon or hydrogen. Illustrative heteroatoms include boron, nitrogen, oxygen, phosphorus, sulfur and selenium.

The term “aryl” is art-recognized and refers to 5-, 6- and 7-membered single-ring aromatic groups that may include from zero to four heteroatoms, for example, benzene, pyrrole, furan, thiophene, imidazole, oxazole, thiazole, triazole, pyrazole, pyridine, pyrazine, pyridazine and pyrimidine, and the like. Those aryl groups having heteroatoms in the ring structure may also be referred to as “aryl heterocycles” or “heteroaromatics.” The aromatic ring may be substituted at one or more ring positions with such substituents as described above, for example, halogen, azide, alkyl, aralkyl, alkenyl, alkynyl, cycloalkyl, hydroxyl, alkoxyl, amino, nitro, sulfhydryl, imino, amido, phosphonate, phosphinate, carbonyl, carboxyl, silyl, ether, alkylthio, sulfonyl, sulfonamido, ketone, aldehyde, ester, heterocyclyl, aromatic or heteroaromatic moieties, —CF₃, —CN, or the like. The term “aryl” also includes polycyclic ring systems having two or more cyclic rings in which two or more carbons are common to two adjoining rings (the rings are “fused rings”) wherein at least one of the rings is aromatic, e.g., the other cyclic rings may be cycloalkyls, cycloalkenyls, cycloalkynyls, aryls and/or heterocyclyls.

The terms ortho, meta and para are art-recognized and refer to 1,2-, 1,3- and 1,4-disubstituted benzenes, respectively. For example, the names 1,2-dimethylbenzene and ortho-dimethylbenzene are synonymous.

The terms “heterocyclyl” or “heterocyclic group” are art-recognized and refer to 3- to about 10-membered ring structures, alternatively 3- to about 7-membered rings, whose ring structures include one to four heteroatoms. Heterocycles may also be polycycles. Heterocyclyl groups include, for example, thiophene, thianthrene, furan, pyran, isobenzofuran, chromene, xanthene, phenoxanthene, pyrrole, imidazole, pyrazole, isothiazole, isoxazole, pyridine, pyrazine, pyrimidine, pyridazine, indolizine, isoindole, indole, indazole, purine, quinolizine, isoquinoline, quinoline, phthalazine, naphthyridine, quinoxaline, quinazoline, cinnoline, pteridine, carbazole, carboline, phenanthridine, acridine, pyrimidine, phenanthroline, phenazine, phenarsazine, phenothiazine, furazan, phenoxazine, pyrrolidine, oxolane, thiolane, oxazole, piperidine, piperazine, morpholine, lactones, lactams such as azetidinones and pyrrolidinones, sultams, sultones, and the like. The heterocyclic ring may be substituted at one or more positions with such substituents as described above, as for example, halogen, alkyl, aralkyl, alkenyl, alkynyl, cycloalkyl, hydroxyl, amino, nitro, sulfhydryl, imino, amido, phosphonate, phosphinate, carbonyl, carboxyl, silyl, ether, alkylthio, sulfonyl, ketone, aldehyde, ester, a heterocyclyl, an aromatic or heteroaromatic moiety, —CF₃, —CN, or the like.

The terms “polycyclyl” or “polycyclic group” are art-recognized and refer to two or more rings (e.g., cycloalkyls, cycloalkenyls, cycloalkynyls, aryls and/or heterocyclyls) in which two or more carbons are common to two adjoining rings, e.g., the rings are “fused rings”. Rings that are joined through non-adjacent atoms are termed “bridged” rings. Each of the rings of the polycycle may be substituted with such substituents as described above, as for example, halogen, alkyl, aralkyl, alkenyl, alkynyl, cycloalkyl, hydroxyl, amino, nitro, sulfhydryl, imino, amido, phosphonate, phosphinate, carbonyl, carboxyl, silyl, ether, alkylthio, sulfonyl, ketone, aldehyde, ester, a heterocyclyl, an aromatic or heteroaromatic moiety, —CF₃, —CN, or the like.

The term “carbocycle” is art-recognized and refers to an aromatic or non-aromatic ring in which each atom of the ring is carbon.

The term “nitro” is art-recognized and refers to —NO₂; the term “halogen” is art-recognized and refers to —F, —Cl, —Br or —I; the term “sulfhydryl” is art-recognized and refers to —SH; the term “hydroxyl” means —OH; and the term “sulfonyl” is art-recognized and refers to —SO₂—. “Halide” designates the corresponding anion of the halogens, and “pseudohalide” has the definition set forth on 560 of “Advanced Inorganic Chemistry” by Cotton and Wilkinson.

The term “carbonyl” is art recognized and includes such moieties as may be represented by the general formulas: 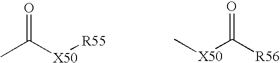
wherein X50 is a bond or represents an oxygen or a sulfur, and R55 and R56 represents a hydrogen, an alkyl, an alkenyl, —(CH₂)ₘ—R61or a pharmaceutically acceptable salt, R56 represents a hydrogen, an alkyl, an alkenyl or —(CH₂)ₘ—R61, where m and R61 are defined above. Where X50 is an oxygen and R55 or R56 is not hydrogen, the formula represents an “ester”. Where X50 is an oxygen, and R55 is as defined above, the moiety is referred to herein as a carboxyl group, and particularly when R55 is a hydrogen, the formula represents a “carboxylic acid”. Where X50 is an oxygen, and R56 is hydrogen, the formula represents a “formate”. In general, where the oxygen atom of the above formula is replaced by sulfur, the formula represents a “thiolcarbonyl” group. Where X50 is a sulfur and R55 or R56 is not hydrogen, the formula represents a “thiolester.” Where X50 is a sulfur and R55 is hydrogen, the formula represents a “thiolcarboxylic acid.” Where X50 is a sulfur and R56 is hydrogen, the formula represents a “thiolformate.” On the other hand, where X50 is a bond, and R55 is not hydrogen, the above formula represents a “ketone” group. Where X50 is a bond, and R55 is hydrogen, the above formula represents an “aldehyde” group.

The terms “alkoxyl” or “alkoxy” are art-recognized and refer to an alkyl group, as defined above, having an oxygen radical attached thereto. Representative alkoxyl groups include methoxy, ethoxy, propyloxy, tert-butoxy and the like. An “ether” is two hydrocarbons covalently linked by an oxygen. Accordingly, the substituent of an alkyl that renders that alkyl an ether is or resembles an alkoxyl, such as may be represented by one of —O-alkyl, —O-alkenyl, —O-alkynyl, —O—(CH₂)ₘ—R61, where m and R61 are described above.

Substitutions may be made to alkenyl and alkynyl groups to produce, for example, aminoalkenyls, aminoalkynyls, amidoalkenyls, amidoalkynyls, iminoalkenyls, iminoalkynyls, thioalkenyls, thioalkynyls, carbonyl-substituted alkenyls or alkynyls.

The definition of each expression, e.g. alkyl, m, n, and the like, when it occurs more than once in any structure, is intended to be independent of its definition elsewhere in the same structure.

Certain compounds of the present disclosure may exist in particular geometric or stereoisomeric forms. In addition, compounds of the present disclosure may also be optically active. The present disclosure contemplates all such compounds, including cis- and trans-isomers, R— and S-enantiomers, diastereomers, (D)-isomers, (L)-isomers, the racemic mixtures thereof, and other mixtures thereof, as falling within the scope of the disclosure. Additional asymmetric carbon atoms may be present in a substituent such as an alkyl group. All such isomers, as well as mixtures thereof, are intended to be included in this disclosure.

If, for instance, a particular enantiomer of compound of the present disclosure is desired, it may be prepared by asymmetric synthesis, or by derivation with a chiral auxiliary, where the resulting diastereomeric mixture is separated and the auxiliary group cleaved to provide the pure desired enantiomers. Alternatively, where the molecule contains a basic functional group, such as amino, or an acidic functional group, such as carboxyl, diastereomeric salts are formed with an appropriate optically-active acid or base, followed by resolution of the diastereomers thus formed by fractional crystallization or chromatographic means well known in the art, and subsequent recovery of the pure enantiomers.

It will be understood that “substitution” or “substituted with” includes the implicit proviso that such substitution is in accordance with permitted valence of the substituted atom and the substituent, and that the substitution results in a stable compound, e.g., which does not spontaneously undergo transformation such as by rearrangement, cyclization, elimination, or other reaction.

The term “substituted” is also contemplated to include all permissible substituents of compounds. In a broad aspect, the permissible substituents include acyclic and cyclic, branched and unbranched, carbocyclic and heterocyclic, aromatic and nonaromatic substituents of compounds. Illustrative substituents include, for example, those described herein above. The permissible substituents may be one or more and the same or different for appropriate compounds. For purposes of this disclosure, the heteroatoms such as nitrogen may have hydrogen substituents and/or any permissible substituents of compounds described herein which satisfy the valences of the heteroatoms. This disclosure is not intended to be limited in any manner by the permissible substituents of organic or inorganic compounds.

For purposes of this disclosure, the chemical elements are identified in accordance with the Periodic Table of the Elements, CAS version, Handbook of Chemistry and Physics, 67th Ed., 1986-87, inside cover. Also for purposes of this invention, the term “hydrocarbon” is contemplated to include all permissible compounds having at least one hydrogen and one carbon atom. In a broad aspect, the permissible hydrocarbons include acyclic and cyclic, branched and unbranched, carbocyclic and heterocyclic, aromatic and nonaromatic organic compounds that may be substituted or unsubstituted.

Fluid Compositions

In one embodiment, a fluid composition with an absorbance of less than about 2 cm⁻¹ at about or less than 220 nm, or about or less than 200 or 157 nm is provided that comprises at least one perfluoroether compound. In some embodiments, a fluid composition is provided that has an absorbance of less than about 5.0 cm⁻¹ a, less than about 3.0 cm⁻¹, less than about 1.9 cm⁻¹, less than about 1.0 cm⁻¹, less than about 0.5 cm⁻¹, or even less that about 0.1 cm⁻¹ at about or less than 220 nm, or about or less than 200 or 157 nm. The fluid composition may additionally have a low absorbance at higher or lower wavelengths, for example an absorbance of less than about 2 cm⁻¹ at a visible light wavelength, or at an extreme ultraviolet wavelength.

The fluid composition may include a variety of perflouroether compounds. Perfluoroether compounds that may be used in such a fluid composition include substantially linear perfluoroether compounds. In another embodiment, the perfluoroether compounds may include substantially cyclic perfluoroether compounds. The fluid composition may comprise both substantially linear and substantially cyclic compounds. In one embodiment, the fluid composition comprises only one perfluoroether compound. In other embodiments, the fluid composition comprises two or more perfluoroether compounds. In a different embodiment, the fluid composition consists essentially of one or more perfluoroether compounds.

In one embodiment, perfluoroether compounds may include the structure: 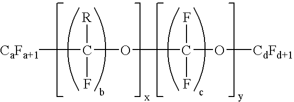
wherein
R is independently, for each occurrence, selected from the group consisting of a perfluoroalkyl moiety and F;
a+b+c+d is the number of carbon atoms in said perfluoroether compound;
2a+2b+2c+2d+2 is the number of fluorine atoms;
a is an integer in the range 1 to 3 inclusive;
b is an integer in the range 0 to 3 inclusive;
c is an integer in the range 0 to 3 inclusive;
d is an integer in the range 1 to 3 inclusive;
x is an integer from 1 to about 20; and
y is an integer from 0 to about 20.

In one embodiment, a is 1. In another embodiment, d is 1. In another embodiment, c is 2. In yet another embodiment b is 2. In another embodiment a=1, d=1, b=2, c=2 and x+y=3. In embodiment, R is CF₃ or C₂F₅.

In another embodiment, perfluoroether compounds may include the cyclic compounds of the structure: 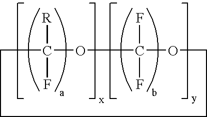
wherein
R is independently, for each occurrence, selected from the group consisting of a perfluoroalkyl moiety and F;
a is an integer from 1 to about 3;
b is an integer from 0 to about 3;
x is an integer from 2 to about 20; and
y is an integer from 0 to about 20.

In an embodiment, R is CF₃ or C₂F₅.

Perfluoroether compounds may include perfluoro(ethylene glycol, dimethyl ether), perfluoro(ethylene glycol, diethyl ether), perfluoro(ethylene glycol) oligomers, perfluoro(propyl ether), perfluorotriglyme and perfluoro-15-crown-5 cyclic ether. In some embodiments, a perfluoroether compound has no more than two, no more than three, or no more than four consecutively bound carbon atoms.

In certain instances, the absorbance of a fluid composition of the present invention at one or more wavelengths (or a range of wavelengths) may be generally related to the purity of the fluid composition. In certain embodiments, the fluid composition of the present invention may be purified (or otherwise prepared) to achieve a desired absorbance. In some embodiments, the fluid composition of the present invention has at least about 99.9% purity by weight, at least 99.99% purity by weight, at least 99.999% purity by weight, or even at least 99.9999% purity by weight of perfluoroether compound(s) in the fluid composition. Impurities in the fluid composition may contribute to a higher absorbance of the fluid at wavelengths less than about 220 nm, less than about 200 nm, or even less than about 157 nm.

In certain instances, it may be possible to determine which compounds will be “impurities,” at least in so much as they would, at a certain concentration (or greater), make a composition not have the desired properties (e.g., optical).

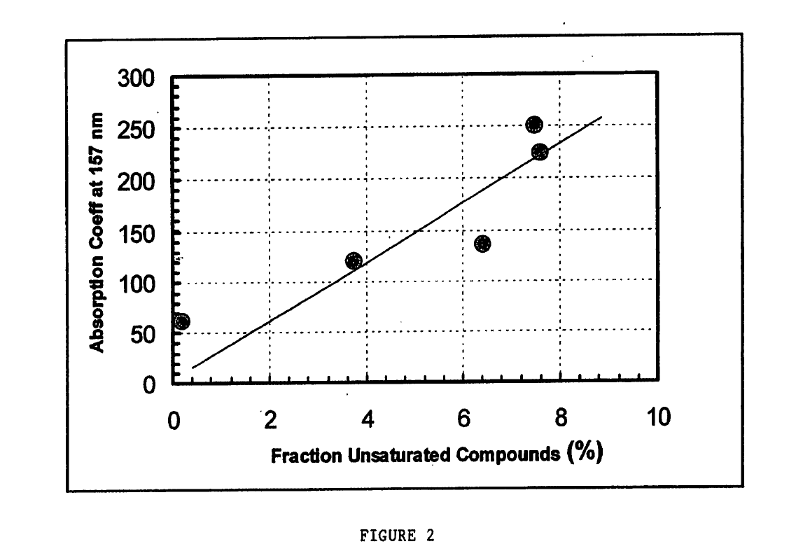

By way of example, certain compounds that absorb below 220 nm would be deemed “impurities” with respect to a subject composition for which having minimal absorbance below that wavelength was desirable. It has been learned that examples of such compounds include those having at least one alkene, e.g., a compound that includes a vinyl group, an aromatic or heteroaromatic ring, or a diene. See, e.g., FIG. 2 for an indication on how unsaturated impurities may affect optical absorbances. Impurities may include those from compounds having at least one carbonyl group, for example, a ketone, an aldehyde, carboxylic acid, ester, anhydride, or an acid fluoride. Compounds which comprise strained ring structures such as an epoxide, or derivatives of cyclopropane or cyclobutane may also be an impurity in such a fluid composition. Compounds that comprise an alkoxy moiety, chlorinated compounds, or metals or metallic salts may be an impurity in such a fluid composition. In some embodiments, unsaturated compounds, including unsaturated compounds with low boiling points, may be such impurities. It is understood that for all of those instances in which the foregoing compounds are understood to be impurities with respect to a subject composition, such composition may contain some of them, but not so much that such composition no longer has the desired characteristics (e.g., optical at a certain wavelength).

In some embodiments, the fluid composition comprises less than 0.01% or even less than 0.001% of a dissolved gas or gasses. In one embodiment, the dissolved gas is oxygen.

It is possible to distinguish the purity of the instant fluid composition by comparison to other fluid compositions that may include perfluorinated compounds. For example, certain subject fluid compositions exhibit lower absorbances as compared to other formulations including perfluorinated compounds.

In certain embodiments, the subject fluid composition may contain materials other than perfluoroether compounds. In certain embodiments, the fluid composition does not contain any appreciable amount of a component that has an absorbance of more than about 2 cm⁻¹. For those subject fluid compositions containing such other materials, it may be important in certain of such embodiments to maintain an absorbance of less than about 2 cm⁻¹, in the fluid composition.

The fluid composition of the present disclosure may have minimal degradation properties, for example, the fluid composition may not degrade with exposure to radiation. In some embodiments, the fluid composition has a vapor pressure between about 0.001 Torr and about 500 Torr. In other embodiments, the fluid composition has a kinematic viscosity between about 0 centipoise and about 300 centipoise.

The subject compositions may be prepared by methods known to those of skill in the art, examples of which are set forth below in the Exemplification section. It is understood that subject compositions and/r components in them may be prepared directly with the desired purity level or may be purified after synthesis to achieve the desired purity level.

For example, fluorination of ethers may be achieved by using, for example, CoF₃. Other methods for preparing perfluoroethers include a surface treatment of polymeric articles, powders or foils with elemental fluorine dissolved in either perfluoropolyether compounds or halogenated hydrocarbons. Liquid phase fluorination for perfluorination may also be used to prepare perfluoroethers.

Perflouroethers may be prepared by the LaMar process, which may allow for the control of the kinetics of the highly exothermic fluorination reaction and for the effective dissipation of he heat of reaction in order to minimize thermal degradation and skeletal fragmentation. The kinetics are typically controlled by using a mixture of fluorine gas highly diluted with helium (e.g., starting fluorine concentration generally 1-3% by volume) in a continuous gas flow system over a solid substrate. By limiting the amount of fluorine available for reaction, the reaction is slowed so heat evolution is controlled and effective heat dissipation is possible. elium may be used not only as a convenient diluent gas, but also, because of its relatively high heat capacity, as an effective heat dissipator. As the reaction proceeds, the partially fluorinated substrates become resistant to further fluorination by dilute fluorine mixtures, so more fluorine-concentrated gas mixtures are used to promote further reaction. The nature of the partially fluorinated substrates slows the reaction kinetics in the concentrated fluorine environments while efficient heat dissipation is still important for keeping skeletal fragmentation to a minimum. The fluorinating agent for this process may be a flourine gas.

Using the LaMar reaction, for example, solid reactants can be fluorinated at room temperature and atmospheric pressure in a horizontal cylindrical fluorine reactor. Such a reactor should be fabricated from materials which are inert to fluorine and the various other reactants. A heating element consisting of a resistance heater wrapped around the cylindrical reactor can be employed to elevate the temperature for fragmentation. Subsequent to or during production of the fluorinated ether, this material is subjected to an elevated temperature. The elevated temperature is chosen to be sufficient to cause fragmentation of the ether. Larger amounts of volatile perfluoroethers and non-volatile oils may be produced using this procedure by fluorinating and fragmenting the perfluoropolymer for longer times at higher temperatures. Higher temperatures may also promote faster and more extensive fragmentation. It is this additional thermal activation energy supplied by the higher temperatures which makes fragmentation a significant process in the free-radical direct fluorination reaction. A suitable temperature range for most materials is between about 55 and 210 C and in some embodiments, a range of about 110° C. to about 200° C.

The purity of the fluid compositions of the invention may be, in some embodiments, enhanced by the use of single precursor compounds or selected (rather than random) mixtures thereof.

Purification methods may include use of solid inorganic absorption agents. These agents may separate, for example, acid components and may also separate unsaturated impurities. Solid inorganic sorption agents include activated carbon and absorbents composed of aluminum oxide or silicon dioxide. Treatment with an absorption agent may be carried out at a temperature from −30° C. to 100° C. Adsorbent compositions may also comprise zeolites and/or a carbonaceous absorbents, for example, molecular sieving carbons having a specific mean micropore size.

Purification methods may include use of wet scrubbers, to for example remove non-desirable, corrosive gases and water reactive or soluble compounds, such as metal etch gases and their reaction products such as HCl. The scrubber products (sodium silicate, sodium fluoride, ethanol, sodium tungstate, etc.) are water soluble and can be readily disposed.

Dry scrubbers may also be used to purify fluid compositions. Typically, a dry scrubber comprises resins or solid particles that may for example remove hydrides.

Distillation processes and phase separation techniques such as filtration, extraction or separation may also be used for purification. Purification processes may be used singularly or in combination with other processes.

Methods of using the fluid composition of this disclosure are also provided. For example, a method of using the fluid composition of this disclosure comprises illuminating light through the fluid composition. A method for resolving features or creating features on a focal substrate, for example, a silicon wafer, comprises illuminating light through a fluid composition of the present disclosure onto the substrate.

Systems and Processes

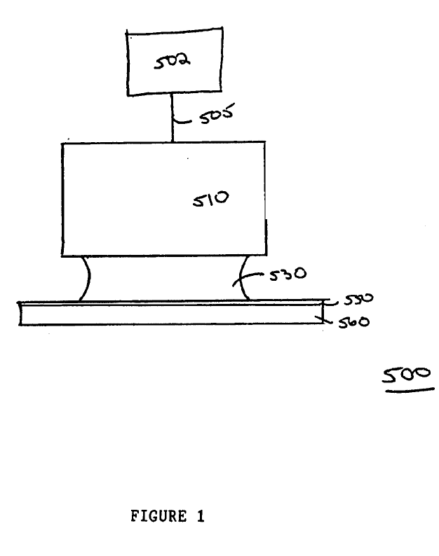

FIG. 1 is a schematic diagram of exemplary embodiment of a system 500 according to aspects of the present disclosure. System 500 comprises an electromagnetic radiation source or illuminating source 502, an imaging optic 510, and a fluid composition of the present disclosure 530. System 500 may be any suitable lithographic or optical system, such as a conventional stepper or a scanner lithographic system. In one embodiment, the system 500 has an imaging optic 510 capable of accommodating the NA arising from a fluid composition 530 between imaging optic 510 and a photosensitive material 550.

Source 502 generates an input beam 505. In some embodiments, source 502 generates at least quasi-coherent illumination. For example, illumination source 502 can include a lamp or a laser light source. In some embodiments, source 502 generates light at or below 220 nm, for example at or below about 157 nm. In one embodiment, source 502 is an excimer laser.

Imaging optic 510 may further include imaging a mask (not shown) onto photosensitive material 550. Photosensitive material 550 can be any known photosensitive material, e.g., a photographic film or a photolithographic resist on a semiconductor substrate 560.

The fluid composition 530 may fill a space between the imaging optic 510 and material 550. The fluid composition 530 is in optical contact with at least a portion of the imaging optic 510 and at least a portion of a surface of material 550. In one embodiment, the fluid composition 530 is reasonably closely index-matched to a component of the imaging optic 510. The index of refraction of the fluid composition may be substantially the same as a component of the imaging optic.

The fluid composition 530 may not, in certain embodiments, interact with material 550 in a manner that would impede image formation. For example, material 550 may not be substantially soluble in the fluid composition 530. In some embodiments, the fluid composition may not chemically react with material 550.

Projection system 500 may be contained in a housing (not shown) that provides a mechanical base for the optical components. The housing may also be used to contain any inert gas used to purge the system of air (e.g., using N₂), as is the standard practice in lithographic systems operating at wavelengths below 650 nm. The housing may rest on translation and rotation stages (not shown) to align the system 500 with material 550. Further, the whole assembly may be supported by a vibration isolation system (not shown), as in conventional lithographic systems.

A process is also provided for modifying a substrate, such as modifying a silicon wafer to create a printed pattern. In one embodiment, a process includes providing a silicon wafer comprising a photoresist layer, providing an imaging optic, introducing a fluid composition comprising at least one perfluoroether compound into a volume between said silicon wafer and said imaging optic; and illuminating light at about 157 nm through said fluid composition onto said silicon wafer. In some embodiments, the fluid composition has an absorbance of less than or equal to about 2 cm⁻¹. In other embodiments a process further comprises modifying the substrate, for example, a silicon wafer so that the substrate may be used as part of another device, for example, a computer device or a memory device.

Devices

A device is also provided, such as a semiconductor device. The device may comprise a printed pattern, etch, or design on or in the surface of the device. The device may be a etched substrate, for example, a silicon substrate or wafer. In one embodiment, a printed pattern on the device comprises a feature with a width less than about 100 nm, less than about 80 nm, less than about 50 nm, less than about 30 nm, or even less about 20 nm. In one embodiment, a device such as a semiconductor device is made by a process comprising introducing a fluid composition comprising at least one perfluoroether compound into a volume between a silicon wafer comprising a photoresist layer, and an imaging optic; wherein said fluid composition has an absorbance of less than about 2 cm⁻¹, less than about 1.5 cm⁻¹, or even less than about 1.0 cm⁻¹, at a wavelength of less than about 200, or a wavelength of less than or about 157 nm. In some embodiments, the device is made by a process further comprising directing optical energy through a fluid composition of the instant disclosure onto a device, for example, a silicon wafer, thereby contributing to the production of said printed pattern.

Exemplification

Materials

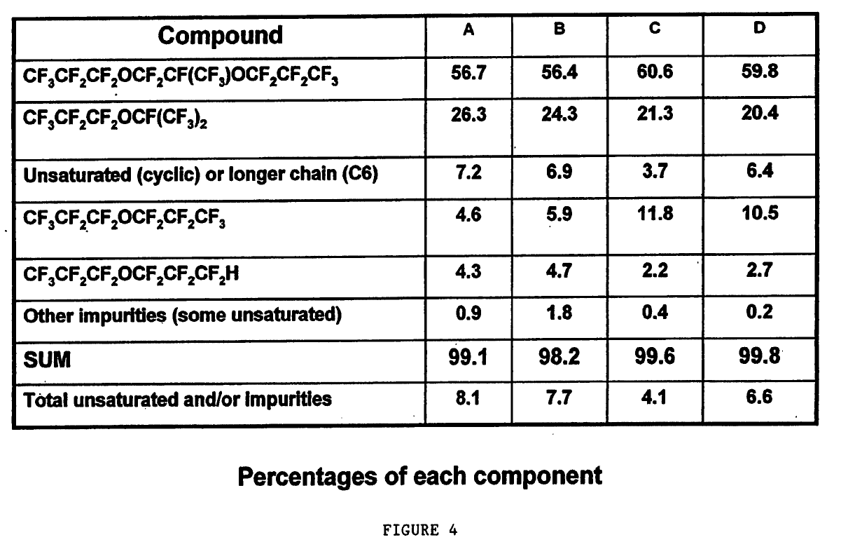

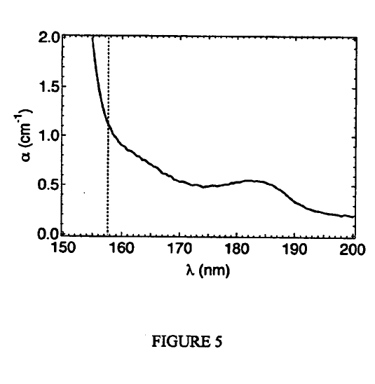

Original samples of commercially available perfluoroethers, examples of which are characterized in FIG. 4, contained impurities that exhibited increased optical absorbance below 220 nm. Accordingly, perfluorotriglyme was specially ordered from Exfluor with instructions to minimize impurities, and the material was prepared in accordance with it is believed the method specified in Example 4 below (or a substantial equivalent). Such material, and other perfluoroethers, may be ordered from Exfluor and other commercial suppliers (optionally on a special order basis). The VUV absorbance spectrum (taken as provided in Example 5 below) for such perfluorotriglyme specially ordered from Exfluor is shown in FIG. 5.

### EXAMPLE 1

Purification of Perfluorotriglyme

Perfluorotriglyme (Exfluor, specially ordered as described above) is distilled at atmospheric pressure using a 12-inch Vigreux column and heat is supplied via a standard heating mantle. The heating rate is controlled so as to maintain a slow, steady rate of condensate (about 2-3 mL/min). The first fraction (10%) is collected between 95-105 C and discarded, and the second fraction (80%) is collected at exactly 105 C (uncorrected) and when the temperature began to change the collection is stopped.

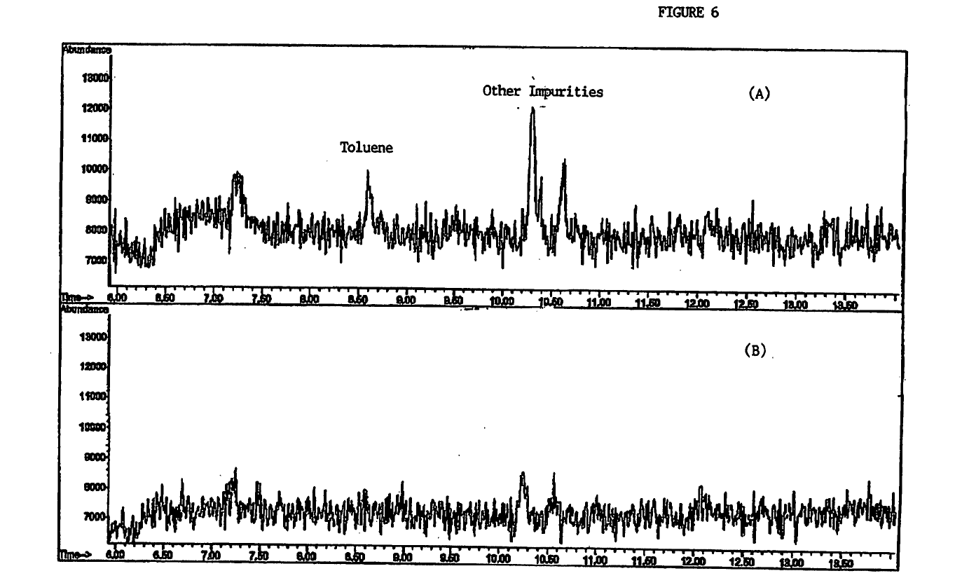

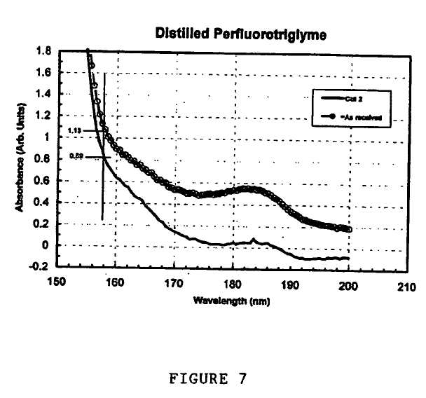

Both of the collected fractions exhibit lower levels (approximately 40-55 ppm) of high boiling impurities (some of which are believed to be chlorinated) that absorb heavily at 157 nm, as compared to the levels detected in the original material of approximately 110 ppm. Gas chromatographs of the results of this purification step for the starting material and the second fraction are shown in FIG. 6(A) and (B). As shown in FIG. 7, the second fraction exhibited an absorbance at about 157 nm of about 0.9 cm⁻¹, as compared to that of about 1.1 cm⁻¹ for the starting material before distillation.

### EXAMPLE 2

Other perfluoroethers will be purified using the methods described herein. For distillation purification, the boiling points for some perfluoroethers are:

| Perfluoroether | Boiling point (C.) |
|---|---|
| Perfluoro-6,6-Bis(Propyloxymethyl)-4,8- | 232 |
| Dioxaundecane | |
| (CF₃)₂CFOCF₂CF₂OCF(CF₃)₂ | 115 |
| CF₃OC(CF₃)₂OCF₂CF₂OCF(CF₃)₂ | 144 |
| Perfluoro[(1-methoxy-1- | 130-140 |
| methylethyl)cyclo-hexane] | |
| Perfluoro[(1-ethoxy-1-methylethyl)cyclo- | 144-154 |
| hexane] | |
| Perfluoro[[(1-methoxy-methoxy)-1- | 146-157 |
| methylethyl]-cyclohexane] | |
| Perfluoro[(1-methoxy-1-methylethyl)- | 144-154 |
| cycloheptane] | |
| Perfluoro[2-methoxy-2-methylpropyl)- | 144-155 |
| cyclopentane] | |
| Perfluoro[(1-methoxy-1- | 114-122 |
| methylethyl)cyclo-pentane] | |
| Perfluoro[1-methyl-1-propoxyethyl)cyclo- | 145-156 |
| pentane] | |
| Perfluoro[(1-methyl-1-isopropoxyethyl)- | 144-154 |
| cyclopentane] | |
| Perfluoro[[1 -(ethoxy-methoxy)-1-methyl- | 147-158 |
| ethy]cyc1opentane] | |
| Perfluoro[(2-ethoxy-1,1-dimethylethoxy)- | 149-159 |
| cyclopentane] | |

### EXAMPLE 3

Alternative Purification of Perfluorotriglyme

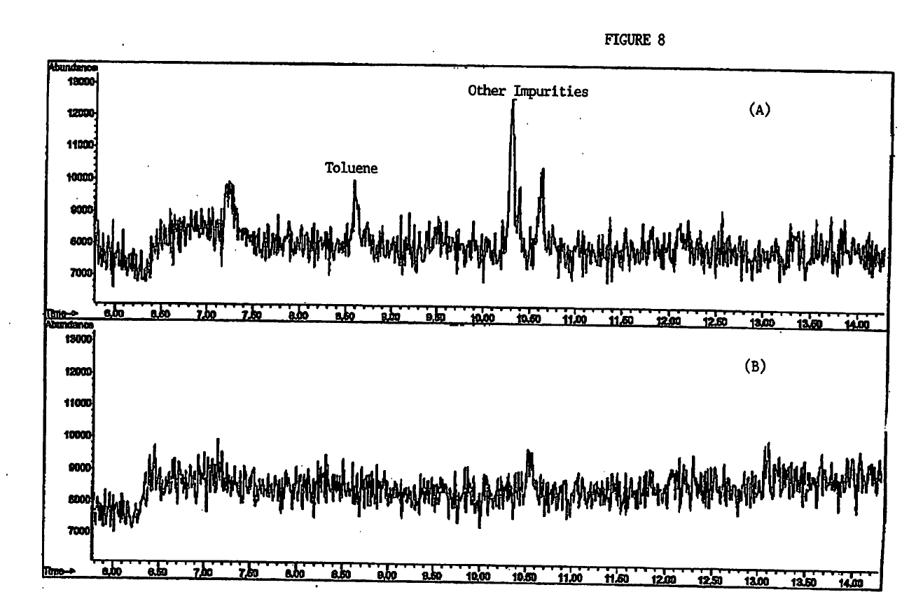

A short column of silica gel (4″×0.5″) is prepared by pouring dry silica into a glass tube. Perfluorotriglyme (Exfluor, specially ordered as described above) is then introduced onto the top of the column and allowed to flow through its length. The first few percent of collected material is discarded and next 60% is saved and analyzed. As shown in FIG. 8, the high boiling impurities (some believed to be chlorinated) originally observed in the starting material were reduced from about 110 ppm to about 3 ppm, and as a result, the purified sample exhibited higher transparency below 220 nm.

Other perfluoroethers will be purified using this or a substantially similar method.

### EXAMPLE 4

Synthesis of Perfluorotriglyme

A solution of triethylene glycol dimethyl ether in hexafluoro-1,1,3,4-tetrachloro butane (or 1,1,2-trichlorotrifluoro ethane) is introduced into a reactor containing more hexafluoro-1,1,3,4-tetrachloro butane, sodium fluoride, and saturated fluorine gas. See U.S. Pat. No. 5093432. A flow of a mixture of helium and fluorine gases was then begun and continued for 24 h. After purging with nitrogen, the product may be isolated by distillation.

### EXAMPLE 5

Measurement of VUV Absorbance of Liquid Compositions

Liquid is degassed by repeated cycling between −200° C. and room temperature under a vacuum of <10⁻⁶ torr until no further evolution of bubbles is observed upon thawing. This degassed liquid is introduced, under N₂ ambient, between the windows of liquid cells consisting of two plane CaF₂ windows separated with a PTFE spacer. The transmission of several different path length (i.e. different PTFE spacer thickness) cells is measured in a VUV spectrophotometer. The absorbance, α, was then determined by a least-squares fit of the equation T=C10^{-αx} where T is the transmission, x is the liquid path length, and C is a constant which accounts for the absorption of the cell windows. The various spectra disclosed herein are usually taken using this method.

Equivalents

While specific embodiments of the subject invention have been discussed, the above specification is illustrative and not restrictive. Many variations of the invention will become apparent to those skilled in the art upon review of this specification. The full scope of the invention should be determined by reference to the claims, along with their full scope of equivalents, and the specification, along with such variations.

Unless otherwise indicated, all numbers expressing quantities of ingredients, reaction conditions, parameters, descriptive features and so forth used in the specification and claims are to be understood as being modified in all instances by the term “about.” Accordingly, unless indicated to the contrary, the numerical parameters set forth in this specification and attached claims are approximations that may vary depending upon the desired properties sought to be obtained by the present invention.

All publications and patents mentioned herein, including those items listed below, are hereby incorporated by reference in their entirety as if each individual publication or patent was specifically and individually indicated to be incorporated by reference. In case of conflict, the present application, including any definitions herein, will control.

Also incorporated by reference are the following:

Patents and Patent Applications

U.S. patent application Ser. No. 20020163629, U.S. Pat. No. 5,900,354; U.S. Pat. No. 6,416,683, U.S. Pat. No. 4,570,004, U.S. Pat. No. 4,523,039, U.S. Pat. No. 4,904,417, U.S. Pat. No. 4,757,145, U.S. Pat. No. 4,8084,72, U.S. Pat. No. 4,889,939, U.S. Pat. No. 5,382,614, U.S. Pat. No. 5,455,373, U.S. Pat. No. 6,416,683, U.S. Pat. No. 5,185,473, U.S. Pat. No. 4,973,716, U.S. Pat. No. 5,254,699, U.S. Pat. No. 4,605,786, U.S. Pat. No. 4,788,350, U.S. Pat. No. 4,523,039, U.S. Pat. No. 4,510,335, U.S. Pat. No. 4,453,028, U.S. Pat. No. 4,675,452, U.S. Pat. No. 6,479,712, U.S. Pat. No. 5,753,776, U.S. Pat. No. 5,674,949, U.S. Pat. No. 5,571,870, U.S. Pat. No. 5,543,567, U.S. Pat. No. 5,539,059, U.S. Pat. No. 5,506,309, U.S. Pat. No. 5,461,117, U.S. Pat. No. 5,455,373, U.S. Pat. No. 5,446,209, U.S. Pat. No. 5,332,790, U.S. Pat. No. 5,322,904, U.S. Pat. No. 5,332,903, U.S. Pat. No. 5,300,683, U.S. Pat. No. 5,202,501, U.S. Pat. No. 5,202,480, U.S. Pat. No. 5,198,139, U.S. Pat. No. 5,132,455, U.S. Pat. No. 5,093,432, U.S. Pat. No. 5,0755,09, U.S. Pat. No. 5,053,536,U.S. Pat. No. 5,032,302,U.S. Pat. No. 5,025,093, U.S. Pat. No. 4,931,199, U.S. Pat. No. 4,925,583, U.S. Pat. No. 4,894,484, U.S. Pat. No. 4,859,747, U.S. Pat. No. 4,827,042, U.S. Pat. No. 4,803,005, U.S. Pat. No. 4,760,198, U.S. Pat. No. 4,755,567, U.S. Pat. No. 5,420,354, U.S. Pat. No. 6,500,994

Publications

Hoffnagle et al., J. Vac. Sci. Technol. B 17(6), pp.3306-3309 (1999); Adcock and Lagow, Org. Chem. 38(20) pp3617-3618 (1977); M. Switkes and M. Rothschild, J. Vac. Sci. Technol. B 19(6), pp.2353-2356 (2001); G. E. Gerhardt and R. J. Lagow, J. Chem. Soc., Chem. Comm. 8, pp.259-260 (1977); G. E. Gerhardt and R. J. Lagow, J. Org. Chem. 43(23), pp.4505-4509 (1978); J. L. Adcock, and M. L. Cherry, J. Fluorine Chem. 30(3), pp.343-350 (1985); W. H. Lin, W. I. Bailey, and R. J. Lagow, Pure and Appl. Chem., 60(4), pp.473-476 (1988); S. Modena et al., J. Fluorine Chem. 40(2-3), pp.349-357 (1988); W. R. Jones, Jr., R. J. Lagow et al., Ind. Eng. Chem Res. 27, pp. 1497-1502 (1988); T.-Y. Lin, R. J. Lagow, et al., J. Am. Chem. Soc. 116, pp. 5172-5179 (1994).

1. A fluid composition comprising at least one perfluoroether compound wherein said fluid composition has an absorbance of less than about 2 cm⁻¹ at a wavelength of about 157 nm.

2. The fluid composition of claim 1, wherein purity of said fluid composition is at least about 99.999% purity by weight of all perfluoroether compounds in said fluid composition.

3. The fluid composition of claim 2, wherein said purity by weight is measured by gas chromatograpy or mass spectrometry.

4. The fluid composition of claim 2, wherein said purity by weight is measured by gas chromatography.

5. The fluid composition of claim 1, wherein said fluid composition comprises less than about 0.001% by weight of dissolved oxygen.

6. The fluid composition of claim 1, wherein said fluid composition comprises less than 0.001% of one or more compounds each comprising at least one moiety selected from: an alkene, a carbonyl, an alkenyl, an alkoxy, and an acid fluoride.

7. The fluid composition of claim 1, wherein said perfluoroether compound comprises a substantially linear perfluoroether compound.

8. The fluid composition of claim 1, wherein said perfluoroether compound comprises a substantially cyclic perfluoroether compound.

9. The fluid composition of claim 7, wherein said perfluoroether compound has the following structure: 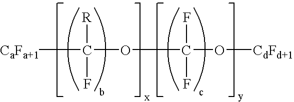
wherein
R is independently, for each occurrence, selected from the group consisting of a perfluoroalkyl moiety and F;
a+b+c+d is the number of carbon atoms in said perfluoroether compound;
2a+2b+2c+2d+2 is the number of fluorine atoms;
a is an integer in the range 1 to 3 inclusive;
b is an integer in the range 0 to 3 inclusive;
c is an integer in the range 0 to 3 inclusive;
d is an integer in the range 1 to 3 inclusive;
x is an integer from 1 to about 20; and
y is an integer from 0 to about 20.

10. The fluid composition of claim 8, wherein said perfluoroether compound has the following structure: 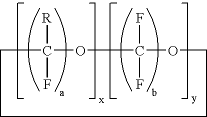
wherein
R is independently, for each occurrence, selected from the group consisting of a perfluoroalkyl moiety and F;
a is an integer from 1 to about 3;
b is an integer from 0 to about 3;
x is an integer from 2 to about 20; and
y is an integer from 0 to about 20.

11. The fluid composition of claim 1, wherein said fluid composition comprises one perfluoroether compound.

12. The fluid composition of claim 1, wherein said fluid composition comprises two or more perfluoroether compounds.

13. The fluid composition of claim 1, wherein components in said fluid composition with an absorbance of greater than about 2 cm⁻¹ at about 157 nm comprise less than about 0.001% by weight of said fluid composition.

14. A method of using the fluid composition of claim 1, wherein said method comprises illuminating light through said fluid composition.

15. A system for optical imaging comprising:
a) an illumination source capable of producing light with a wavelength of about 157 nm;
b) a focal surface;
c) an imaging optic; and
d) a fluid composition disposed between said focal surface and said imaging optics, wherein said fluid composition comprises at least one perfluoroether compound, and wherein said fluid composition has an absorbance of less than about 2 cm⁻¹ at about 157 nm.

16. The system of claim 15, wherein said fluid composition has at least about 99.999% purity by weight of all the perfluoroether compounds in said fluid composition, as measured with mass spectrometry.

17. The system of claim 15, wherein said focal surface comprises a photoresist material disposed on a substrate.

18. The system of claim 17, wherein said substrate comprises a silicon wafer.

19. The system of claim 15, wherein said imaging optic comprises a lens.

20. A semiconductor device comprising a printed pattern, wherein said printed pattern comprises a feature with a width less than about 30 nm, and wherein said semiconductor device is made by a process comprising
a) introducing a fluid composition comprising at least one perfluoroether compound into a volume between a silicon wafer comprising a photoresist layer, and an imaging optic; wherein said fluid composition has an absorbance of less than about 2 cm⁻¹ at about 157 nm;
b) directing optical energy through said fluid composition onto said silicon wafer, thereby contributing to the production of said printed pattern.

21. A process of modifying a silicon wafer comprising:
a) providing a silicon wafer comprising a photoresist layer;
b) providing an imaging optic;
c) introducing a fluid composition comprising at least one perfluoroether compound into a volume between said silicon wafer and said imaging optic; and
d) illuminating light at about 157 nm through said fluid composition onto said silicon wafer, thereby creating a printed pattern on said silicon wafer.

22. The process of claim 21, wherein introducing a fluid composition includes said fluid composition having an absorbance of less than about 2 cm⁻¹.

23. The process of claim 21, wherein said process further comprises modifying said silicon wafer so that said silicon wafer may be used in a computer device.

24. The process of claim 21, wherein said process further comprises modifying said silicon wafer so that said silicon wafer may be used in a memory device.
